(19) United States
(12) Patent Application Publication
(10) Pub. No.: US 2018/0337172 A1
(43) Pub. Date: Nov. 22, 2018

(54) Semiconductor Device

(71) Applicant: Sanken Electric Co., LTD., Niiza-shi (JP)

(72) Inventors: Taro Kondo, Niiza-shi (JP); Shunsuke Fukunaga, Niiza-shi (JP); Shinji Kudo, Niiza-shi (JP)

(73) Assignee: Sanken Electric Co., LTD., Niiza-shi (JP)

(21) Appl. No.: 15/600,003

(22) Filed: May 19, 2017

(51) Int. Cl. H01L 27/06; H01L 29/423; H01L 29/40

(52) U.S. Cl. CPC H01L 27/0629; H01L 29/407; H01L 29/4236; H01L 27/0652

(57) ABSTRACT

A semiconductor device includes: three or more transistors, which are formed on a semiconductor substrate and arranged in one direction; and a PN junction diode, which is formed in a part of a region between the transistors, wherein each of the transistors includes: a trench: a conductive region; and an insulating film, wherein a first thickness of a first insulating film is a thickness between an end portion of a first conductive region on a bottom surface side of the first trench and a bottom surface of the first trench, wherein a second thickness of a second insulating film is a thickness between an end portion of a second conductive region on a bottom surface side of the second trench and a bottom surface of the second trench and wherein the first thickness is thicker than the second thickness.

### TECHNICAL FIELD

This disclosure relates to a semiconductor device.

### BACKGROUND

There has been known a semiconductor device such as a power metal-oxide-semiconductor field-effect transistor (MOSFET) or an insulated gate bipolar transistor (IGBT) in which a gate electrode and a gate insulating film are formed on an inner wall of a trench formed in a front surface of a semiconductor substrate.

A semiconductor device is disclosed in US 2016/0013311 in which a PN junction diode is formed between two left transistors and two right transistors out of four transistors arranged in one direction.

### SUMMARY

In the semiconductor device disclosed in US 2016/0013311, for example, a configuration is adopted in which the depth of the trench of the transistors located at each end out of four transistors is deeper than that of the trench of the transistors adjacent to the PN junction diode. According to this configuration, the breakdown occurs in two transistors adjacent to the PN junction diode earlier than that in the transistors at each end. Therefore, the breakdown current can flow to the PN junction diode, and breakdown resistance can be improved.

However, in this semiconductor device, in order to improve the breakdown resistance, it is necessary to design precisely a condition, and the like, such as a depth of the trench, thereby increasing the design cost.

This disclosure is to provide a semiconductor device in which a high withstand voltage can be realized with a simple configuration.

This disclosure at least discloses the following configurations

According to this disclosure, a semiconductor device includes: three or more transistors, which are formed on a semiconductor substrate and arranged in one direction; and a PN junction diode, which is formed in a part of a region between the transistors formed on the semiconductor substrate. The transistor includes: a trench, which is formed inwardly from a front surface of the semiconductor substrate; a conductive region, which is configured by at least one conductor formed in the trench; and an insulating film, which is formed in a portion of the trench in which the conductive region is not formed. A first trench is a trench of the transistor which is not adjacent to the PN junction diode, a first conductive region is the conductive region of the transistor which is not adjacent to the PN junction diode, and a first insulating film is the insulating film of the transistor which is not adjacent to the PN junction diode. A second trench is the trench of one or both of the two transistors which are adjacent to the PN junction diode, a second conductive region is the conductive region of the transistor, a second insulating film is the insulating film of the transistor. A first thickness of the first insulating film is a thickness between an end portion of the first conductive region on a bottom surface side of the first trench and a bottom surface of the first trench, a second thickness of the second insulating film is a thickness between an end portion of the second conductive region on a bottom surface side of the second trench and a bottom surface of the second trench. The first thickness is thicker than the second thickness.

In the above-described semiconductor device, the second thickness may be 0.2 times to 0.8 times of the first thickness.

In the above-described semiconductor device, a third thickness of the first insulating film is a thickness between each end in a direction of the end portion of the first conductive region on the bottom surface side of the first trench and a side surface of the first trench and a fourth thickness of the second insulating film is a thickness between each end in the direction of the end portion of the second conductive region on the bottom surface side of the second trench and a side surface of the second trench. The third thickness may equal to the fourth thickness.

In the above-described semiconductor device, the end portion of the first conductive region on the bottom surface side of the first trench may be a plane parallel to the front surface of the semiconductor substrate, and the bottom surface of the first trench may be a curved surface protruding to a direction apart from the front surface of the semiconductor substrate, the end portion of the second conductive region on the bottom surface side of the second trench may be a curved surface protruding to the direction apart from the font surface of the semiconductor substrate, and the bottom surface of the second trench may be a curved surface protruding to the direction apart from the front surface of the semiconductor substrate.

In the above-described semiconductor device, the first insulating film may not include a metal, and wherein the second insulating film may include a metal.

In the above-described semiconductor device, each of the first insulating film and the second insulating film may include a metal, and wherein a metal density of the second insulating film may be higher than that of the first insulating film.

According to this disclosure, it is possible to provide a semiconductor device in which a high withstand voltage can be realized with a simple configuration.

### BRIEF DESCRIPTION OF THE DRAWINGS

The foregoing and additional features and characteristics of this disclosure will become more apparent from the following detailed descriptions considered with the reference to the accompanying drawings, wherein:

FIG. 1 is a sectional view partially illustrating a schematic configuration of a semiconductor device 100 according to an embodiment of this disclosure;

FIGS. 2A and 2B are enlarged views illustrating an interior of a first trench 15 and a second trench 16 in the semiconductor device 100 illustrated in FIG. 1;

FIG. 3 is a sectional view partially illustrating a schematic configuration of a semiconductor device 200 according to an embodiment of this disclosure;

FIG. 4 is a sectional view partially illustrating a schematic configuration of a semiconductor device 300 according to an embodiment of this disclosure; FIG. 5 is a sectional view partially illustrating a schematic configuration of a semiconductor device 400 according to an embodiment of this disclosure; and

FIG. 6 is a sectional view partially illustrating a schematic configuration of a semiconductor device 500 according to an embodiment of this disclosure.

### DETAILED DESCRIPTION

An embodiment of this disclosure will be described below with reference to the accompanying drawing.

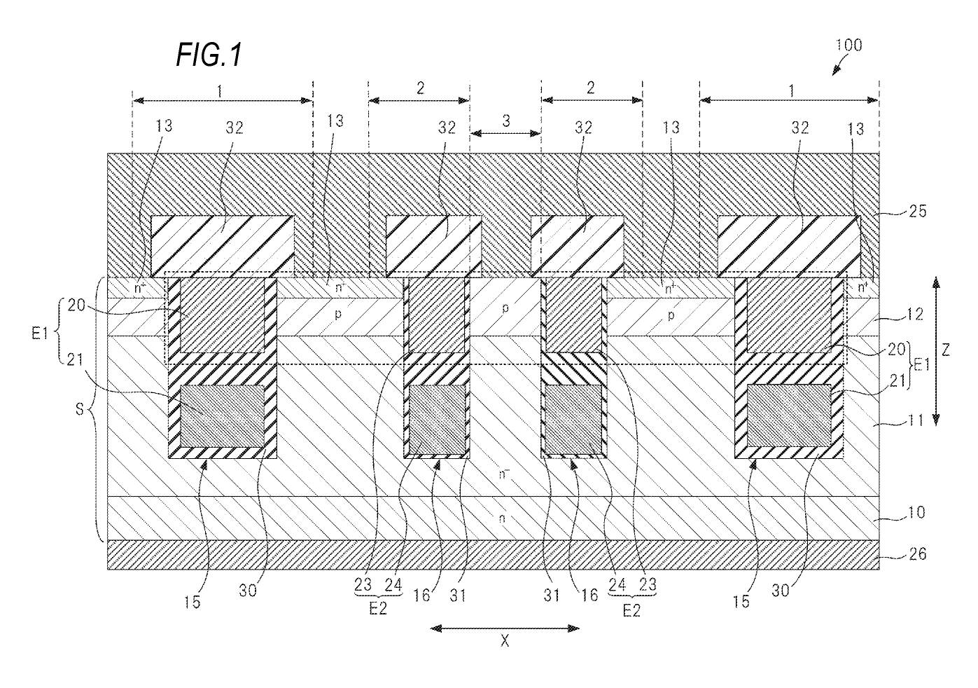

FIG. 1 is a sectional view partially illustrating a schematic configuration of a semiconductor device 100 according to an embodiment of this disclosure.

The semiconductor device 100 includes three or more transistors (a plurality of MOSFETs 1 and a plurality of MOSFETs 2 in an example of FIG. 1) arranged in a direction X (one direction) on a semiconductor substrate S and a PN junction diode 3 formed in a part of a region between the transistors formed on the semiconductor substrate S. FIG. 1 schematically illustrates a section of the semiconductor device 100 in the direction X.

In the semiconductor device 100, as illustrated in FIG. 1, two MOSFETs 2 are formed between two MOSFETs 1 arranged in the direction X, and the PN junction diode 3 is formed between two MOSFETs 2. In the semiconductor device 100, a plurality of sets of two MOSFETs 1, two MOSFETs 2, and the PN junction diode 3 are arranged in the direction X as illustrated in FIG. 1, but at least one set may be provided.

The semiconductor device 100 includes a semiconductor substrate S made of a semiconductor such as silicon, silicon carbide (SiC), or gallium nitride (GaN). The material of the semiconductor substrate S is not limited thereto.

The semiconductor substrate S includes a front surface serving as an upper surface in FIG. 1 and a back surface serving as a lower surface in FIG. 1. In the following description, in a thickness direction Z being an aligned direction of the back surface and the front surface of the semiconductor substrate S, a direction toward the front surface from the back surface is defined as an upward direction, and a direction toward the back surface from the front surface is defined as a downward direction.

The semiconductor substrate S includes an n-type substrate 10, an n-type drift region 11 that is formed on the substrate 10 and has a lower impurity concentration than the substrate 10, a body region 12 that is formed on the drift region 11 to be a p-type impurity region, a source region 13 that are formed on a part of the surface of the body region 12 to be an n-type impurity region having a higher impurity concentration than the drift region 11. Each of the drift region 11 and the body region 12 may be configured to have a structure in which a plurality of layers having different impurity concentrations are laminated.

The semiconductor substrate S further includes a first trench 15 that is formed inwardly from the front surface of the semiconductor substrate S (downward from the front surface) and forms a part of the MOSFET 1 and a second trench 16 that is formed inwardly from the front surface of the semiconductor substrate S (downward from the front surface) and forms the MOSFET 2.

The first trench 15 reaches the interior of the drift region 11 from the front surface of the semiconductor substrate S, and extends in a direction perpendicular to each of the direction X and the thickness direction Z.

In the first trench 15, a field plate electrode 21 is formed on the back surface of the semiconductor substrate S, and a gate electrode 20 of a first electrode is formed above the field plate electrode 21.

In addition, a first insulating film 30 is formed in a portion of the first trench 15 in which the gate electrode 20 and the field plate electrode 21 are not formed.

The second trench 16 reaches the interior of the drift region 11 from the front surface of the semiconductor substrate S, and extends in a direction perpendicular to each of the direction X and the thickness direction Z.

In the second trench 16, a field plate electrode 24 is formed on the back surface of the semiconductor substrate S, and a gate electrode 23 of a second electrode is formed above the field plate electrode 24.

In addition, an insulating film 31 is formed in a portion of the second trench 16 in which the gate electrode 23 and the field plate electrode 24 are not formed.

The n-type source region 13 is formed between the first trench 15 and the second trench 16 on the front surface of the semiconductor substrate S, and the p-type body region 12 is formed below the source region 13. A lower end of each of the gate electrode 20 and the gate electrode 23, which are formed in the first trench 15 and the second trench 16 to hold the body region 12, is located below a lower end of the body region 12.

The p-type body region 12 is formed on the front surface of the semiconductor substrate S between two adjacent second trenches 16. The PN junction diode 3 is formed with the body region 12 formed between two adjacent second trenches 16 and the drift region 11 and the substrate 10 formed below the body region 12.

The semiconductor device 100 also includes a drain electrode 26 that is formed on the back surface of the semiconductor substrate S and is made of a metal such as aluminum or a metal alloy, an interlayer insulating film 32 such as a BPSG (Boron Phosphorus Silicon Glass) film or a PSG film that is formed on the front surface of the semiconductor substrate S to cover the gate electrode 20, the gate electrode 23, a portion of the source region 13, and a portion of the body region 12, and a source electrode 25 that is formed on the front surface of the semiconductor substrate S and on the surface of the interlayer insulating film 32 and is made of a metal such as aluminum or a metal alloy.

The source electrode 25 is electrically connected to the source region 13 and the body region 12 which are exposed on the front surface of the semiconductor substrate S.

In the first trench 15, the gate electrode 20 is connected to a wiring (not illustrated) so that a voltage to be applied is controlled. The gate electrode 20 is a conductor made of a conductive material such as a metal, a metal alloy, a polycrystal semiconductor such as polysilicon polysilicon.

By the control of the voltage to be applied to the gate electrode 20, a channel is formed in the body region 12 adjacent to the first trench 15, and charges can be transferred to the drain electrode 26 from the source region 13 adjacent to the first trench 15 through the drift region 11 and the substrate 10.

The field plate electrode 21 formed in the first trench 15 is connected to the source electrode 25 at the same potential or is in a floating state, and has a function to relax concentration of an electric field in the vicinity of the lower end of the gate electrode 20. The field plate electrode 21 is a conductor made of a conductive material such as a metal, a metal alloy, or a polycrystal semiconductor such as polysilicon.

A first conductive region El is configured by a region where the gate electrode 20 and the field plate electrode 21 are formed.

In the first trench 15, the first insulating film 30 includes an oxide film made of silicon dioxide, a nitride film made of silicon nitride, or a mixed film of the oxide film and the nitride film.

The MOSFET 1 is configured with the gate electrode 20, the field plate electrode 21, and the first insulating film 30 which are formed in the first trench 15, the source region 13 and the body region 12 adjacent to the first trench 15, the drift region 11 and the substrate 10 which are located below the body region 12, the source electrode 25, and the drain electrode 26.

In the second trench 16, the gate electrode 23 is connected to a wiring (not illustrated) so that a voltage to be applied is controlled. The gate electrode 23 is a conductor made of a conductive material such as a metal, a metal alloy, or a polycrystal semiconductor such as polysilicon.

The field plate electrode 24 formed in the first trench 16 is connected to the source electrode 25 at the same potential or is in a floating state, and has a function to relax concentration of an electric field in the vicinity of a lower end of the gate electrode 23. The field plate electrode 24 is a conductor made of a conductive material such as a metal, a metal alloy, or a polycrystal semiconductor such as polysilicon.

A second conductive region E2 is configured by a region where the gate electrode 23 and the field plate electrode 24 are formed.

In the second trench 16, the second insulating film 31 includes an oxide film made of silicon dioxide, a nitride film made of silicon nitride, or a mixed film of the oxide film and the nitride film.

The MOSFET 2 is configured with the gate electrode 23, the field plate electrode 24, and the second insulating film 31 which are formed in the second trench 16, the source region 13 and the body region 12 adjacent to the second trench 16, the drift region 11 and the substrate 10 which are located below the body region 12, the source electrode 25, and the drain electrode 26.

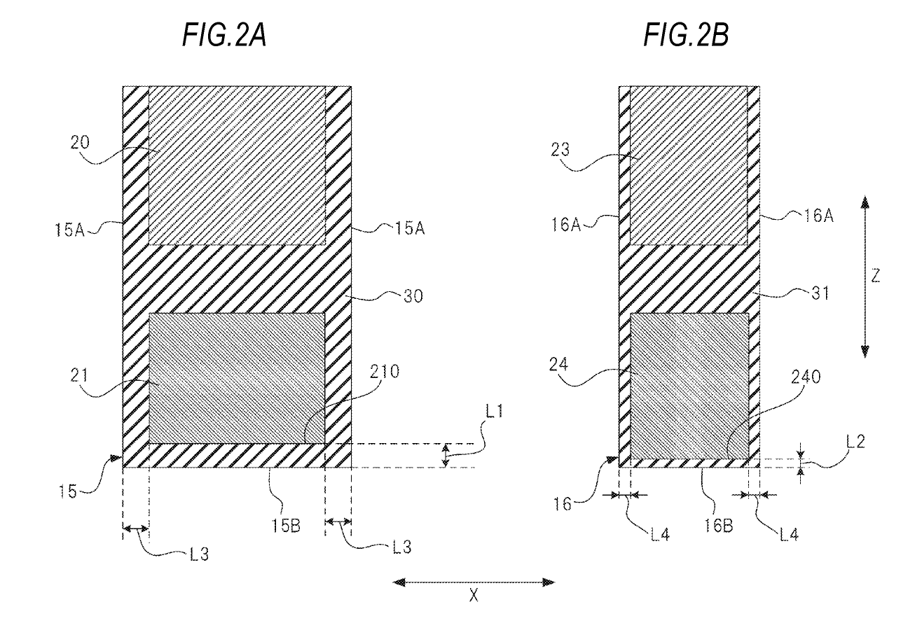

FIGS. 2A and 2B are enlarged views illustrating an interior of the first trench 15 and the second trench 16 in the semiconductor device 100 illustrated in FIG. 1.

The sectional shape of the first trench 15 is a rectangular shape which is longitudinal in the thickness direction Z. The inner wall surface of the first trench 15 is configured with a side surface 15A parallel to the thickness direction Z, and a bottom surface 15B parallel to the direction X.

The sectional shape of the gate electrode 20 and the field plate electrode 21 in the first trench 15 is a rectangular shape having the same width in the direction

X. The end portion (the lower end of the field plate electrode 21) 210 of the first trench 15 of the first conductive region El including the gate electrode 20 and the field plate electrode 21 on the bottom surface 15B side is a plane parallel to the front surface of the semiconductor substrate S.

The sectional shape of the second trench 16 is a rectangular shape which is longitudinal in the thickness direction Z. The inner wall surface of the second trench 16 is configured with a side surface 16A parallel to the thickness direction Z and a bottom surface 16B parallel to the direction X.

The sectional shape of the gate electrode 23 and the field plate electrode 24 in the second trench 16 is a rectangular shape having the same width in the direction X. The end portion (the lower end of the field plate electrode 24) 240 of the second trench 16 of the second conductive region E2 including the gate electrode 23 and the field plate electrode 24 on the bottom surface 16B side is a plane parallel to the front surface of the semiconductor substrate S.

A first thickness L1 of a first insulating film 30 between the end portion 210 and the bottom surface 15B in the first trench 15 in the thickness direction Z is thicker than a second thickness L2 of the second insulating film 31 between the end portion 240 and the bottom surface 16B in the second trench 16 in the thickness direction Z.

A third thickness L3 of the first insulating film 30 between each end of the gate electrode 20 and the field plate electrode 21 in the direction X and the side surface 15A of the first trench 15 is thicker than a fourth thickness L4 of the second insulating film 31 between each end of the gate electrode 23 and the field plate electrode 24 in the direction X and the side surface 16A of the second trench 16.

That is, a distance from each end of the end portion 210 of the field plate electrode 21 in the first trench 15 in the direction X to the side surface 15A is longer than a distance from each end of the end portion 240 of the field plate electrode 24 in the second trench 16 in the direction X to the side surface 16A.

In the semiconductor device 100 configured as above, an electric field concentrates on the vicinity of the bottom surface 15B of the first trench 15 and the vicinity of the bottom surface 16B of the second trench 16. However, since the first thickness L1 is thicker than the second thickness L2, a breakdown occurs in the MOSFET 2 earlier than that in the MOSFET 1. At this time, breakdown current flows to the PN junction diode, and thus breakdown resistance can be improved. Since such an effect can be realized only by controlling a thickness of the insulating film, it is possible to reduce a fabricating cost of a device.

In the semiconductor device 100, since the third thickness L3 is thicker than the fourth thickness L4, it is possible to enhance the effect that the breakdown occurs in the MOSFET 2 earlier than that in the MOSFET 1. As a result, the breakdown resistance of the MOSFET 1 can be improved to make a high withstand voltage in the semiconductor device 100.

Incidentally, a difference between the first thickness L1 and the second thickness L2 is arbitrary. However, in order to secure a withstand voltage of the MOSFET 2, it is preferable that the lower limit of the second thickness L2 be 0.2 times of the first thickness L1. In order to reliably obtain the effect that the breakdown occurs first in the MOSFET 2, it is preferable that the upper limit of the second thickness L2 be 0.8 times of the first thickness L1. For the same reason, it is preferable that the fourth thickness L4 be 0.2 times to 0.8 times of the third thickness L3.

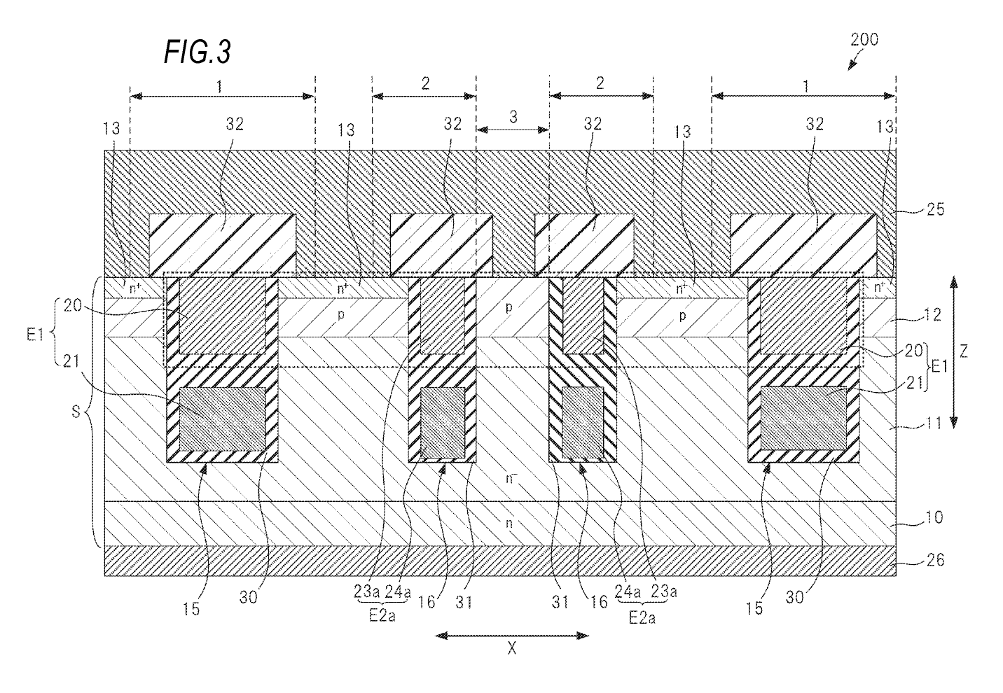

FIG. 3 is a sectional view partially illustrating a schematic configuration of a semiconductor device 200 as an embodiment of the semiconductor device of this disclosure. The semiconductor device 200 has the same configuration as the semiconductor device 100 except the inner structure of the second trench 16. In FIG. 3, the same component as in FIG. 1 is denoted by the same reference numeral.

A second conductive region E2a including a gate electrode 23a and a field plate electrode 24a is formed in the second trench 16 of the semiconductor device 200, and the second insulating film 31 is formed in a portion excluding the second conductive region E2a in the second trench 16.

The gate electrode 23a is obtained by reducing the width of the gate electrode 23 illustrated in FIG. 1 in the direction X. The field plate electrode 24a is obtained by reducing the width of the field plate electrode 24 illustrated in FIG. 1 in the direction X. The thickness of the second insulating film 31 between each end of the gate electrode 23a and the field plate electrode 24a in the direction X and the side surface 16A of the second trench 16 is the same as the third thickness L3 illustrated in FIG. 2A.

In the semiconductor device 200 configured as above, an electric field concentrates on the vicinity of the bottom surface 15B of the first trench 15 and the vicinity of the bottom surface 16B of the second trench 16. However, the thickness of the first insulating film 30 between the lower end of the field plate electrode 21 and the bottom surface 15B of the first trench 15 is thicker than the thickness of the second insulating film 31 between the lower end of the field plate electrode 24a and the bottom surface 16B of the second trench 16. For this reason, the breakdown occurs in the MOSFET 2 earlier than that in the MOSFET 1. As a result, the breakdown resistance of the MOSFET 1 can be improved to make a high withstand voltage in the semiconductor device 200.

In the semiconductor device 200, since the thickness of the second insulating film 31 between each end of the gate electrode 23a and the field plate electrode 24a in the direction X and the side surface 16A of the second trench 16 is the same as the third thickness L3, the capacitance of the MOSFET 2 can be set smaller than that of the semiconductor device 100 to enable high-speed switching.

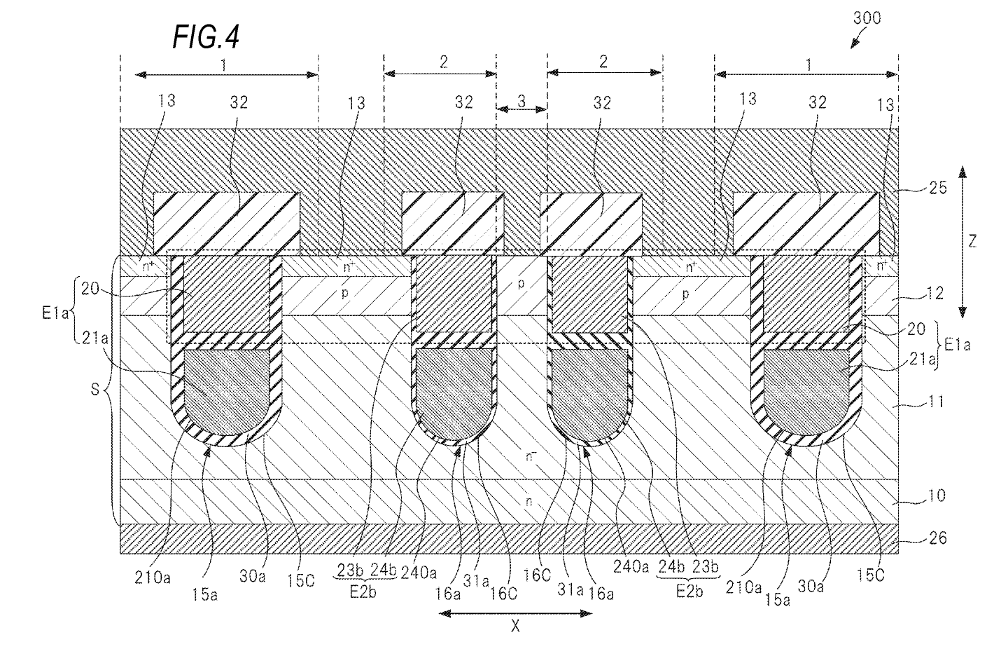

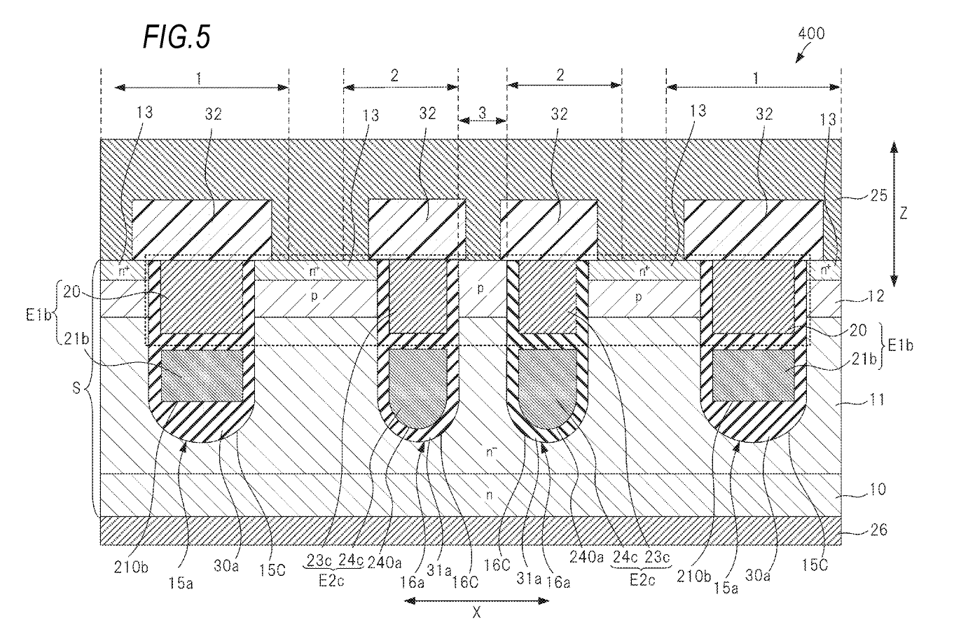

FIG. 4 is a sectional view partially illustrating a schematic configuration of a semiconductor device 300 as an embodiment of the semiconductor device of this disclosure. The semiconductor device 300 has the same configuration as the semiconductor device 100 except that the first trench 15 is changed to a first trench 15a, and the second trench 16 is changed to a second trench 16a. In FIG. 4, the same component as in FIG. 1 is denoted by the same reference numeral.

The sectional shape of the first trench 15a is a shape in which the bottom surface 15B is changed to a curved surface 15C protruding to the direction apart from the front surface of the semiconductor substrate S in the first trench 15 illustrated in FIG. 1.

The gate electrode 20 and a field plate electrode 21a are formed in the first trench 15a, and configure a first conductive region Ela. The arrangement, the function, and the material of the field plate electrode 21a are the same as those of the field plate electrode 21.

In the first trench 15a, a first insulating film 30a is formed in a portion excluding the first conductive region Ela. The material of the first insulating film 30a is the same as that of the first insulating film 30.

The sectional shape of the field plate electrode 21a is a shape in which the end portion 210 is changed to a curved surface 210a protruding to the direction apart from the front surface of the semiconductor substrate S in the field plate electrode 21 illustrated in FIG. 1.

The sectional shape of a second trench 16b is a shape in which the bottom surface 16B is changed to a curved surface 16C protruding to the direction apart from the front surface of the semiconductor substrate S in the second trench 16 illustrated in FIG. 1.

A gate electrode 23b and a field plate electrode 24b are formed in the second trench 16a, and configure a second conductive region E2b. The function and the material of the gate electrode 23b are the same as those of the gate electrode 23. The function and the material of the field plate electrode 24b are the same as those of the field plate electrode 24.

In the second trench 16a, a second insulating film 31a is formed in a portion excluding the second conductive region E2b. The material of the second insulating film 31a is the same as that of the second insulating film 31.

The sectional shape of the field plate electrode 24b is a shape in which the end portion 240 is changed to a curved surface 240a protruding to the direction apart from the front surface of the semiconductor substrate S in the field plate electrode 24 illustrated in FIG. 2B.

In the semiconductor device 300, a first thickness (an average value of lengths of lines which connect the respective points on the curved surface 210a and the curved surface 15C by the shortest distance) of the first insulating film 30a between the curved surface 210a and the curved surface 15C is thicker than a second thickness (an average value of lengths of lines which connect the respective points on the curved surface 240a and the curved surface 16C by the shortest distance) of the second insulating film 31a between the curved surface 240a and the curved surface 16C.

In the semiconductor device 300 configured as above, an electric field concentrates on the vicinity of the curved surface 15C of the first trench 15a and the vicinity of the curved surface 16C of the second trench 16a. However, the first thickness of the first insulating film 30a between the lower end of the field plate electrode 21a and the curved surface 15C of the first trench 15a is thicker than the second thickness of the second insulating film 31a between the lower end of the field plate electrode 24b and the curved surface 16C of the second trench 16b. For this reason, the breakdown occurs in the MOSFET 2 earlier than that in the MOSFET 1. As a result, the breakdown current flows to the diode formed between the second trenches, and a parasitic bipolar transistor is not turned on, so that the breakdown resistance of the device is improved.

In the semiconductor device 300, a fourth thickness of the second insulating film 31a between each end of the gate electrode 23b and the field plate electrode 24b in the direction X and the side surface of the second trench 16b is thinner than a third thickness of the first insulating film 30a between each end of the gate electrode 20 and the field plate electrode 21a in the direction X and the side surface of the first trench 15a. For this reason, it is possible to further enhance the effect that the breakdown occurs in the MOSFET 2 earlier than that in the MOSFET 1. As a result, the breakdown current flows to the diode formed between the second trenches, and a parasitic bipolar transistor is not turned on, so that the breakdown resistance of the device is improved.

Also in the semiconductor device 300, a difference between the first thickness and the second thickness is arbitrary. However, it is preferable that the second thickness be 0.2 times to 0.8 times of the first thickness. In addition, it is preferable that the fourth thickness be 0.2 times to 0.8 times of the third thickness.

FIG. 5 is a sectional view partially illustrating a schematic configuration of a semiconductor device 400 as an embodiment of the semiconductor device of this disclosure. The semiconductor device 400 has the same configuration as the semiconductor device 300 except the shape of the field plate electrode in the first trench 15a, and the size of the gate electrode and the field plate electrode in the second trench 16a. In FIG. 5, the same component in FIG. 4 is denoted by the same reference numeral.

A second conductive region E2c including a gate electrode 23c and a field plate electrode 24c is formed in the second trench 16a of the semiconductor device 400, and the second insulating film 31a is formed in a portion excluding the second conductive region E2c in the second trench 16a.

The gate electrode 23c is obtained by reducing the width of the gate electrode 23b illustrated in FIG. 4 in the direction X. The field plate electrode 24c is obtained by narrowing a width of the field plate electrode 24b illustrated in FIG. 4 in the direction X, and changing a position of the curved surface 240a to a slightly upper position.

A first conductive region E1b including the gate electrode 20 and a field plate electrode 21b is formed in the first trench 15a of the semiconductor device 400, and the first insulating film 30a is formed in a portion excluding the first conductive region E1b in the first trench 15a.

The field plate electrode 21b is obtained by changing the curved surface 210a of the field plate electrode 21a in FIG. 4 to a plane 210b parallel to the front surface of the semiconductor substrate S.

The thickness of the second insulating film 31a between each end of the gate electrode 23c and the field plate electrode 24c in the direction X and the side surface of the second trench 16a is the same as the thickness of the first insulating film 30a between each end of the gate electrode 20 and the field plate electrode 21b in the direction X and the side surface of the first trench 15a.

The first thickness (an average value of lengths of lines which extend from the respective points on the plane 210b in the thickness direction Z and reach the curved surface 15C) of the first insulating film 30a between the plane 210b and the curved surface 15C is thicker than the second thickness (an average value of lengths of lines which connect the respective points on the curved surface 240a and the curved surface 16C by the shortest distance) of the second insulating film 31a between the curved surface 240a and the curved surface 16C. The difference between the first thickness and the second thickness is arbitrary. However, it is preferable that the second thickness be 0.2 times to 0.8 times of the first thickness.

In the semiconductor device 400 configured as above, the thickness of the first insulating film 30a between the lower end of the field plate electrode 21b and the curved surface 15C of the first trench 15a is thicker than the thickness of the second insulating film 31a between the lower end of the field plate electrode 24c and the curved surface 16C of the second trench 16a. For this reason, the breakdown occurs in the MOSFET 2 earlier than that in the MOSFET 1. As a result, the breakdown current flows to the diode formed between the second trenches, and a parasitic bipolar transistor is not turned on, so that the breakdown resistance of the device is improved.

In the semiconductor device 400, the thickness of the second insulating film 31a between each end of the gate electrode 23c and the field plate electrode 24c in the direction X and the side surface of the second trench 16a is the same as the thickness of the first insulating film 30a between each end of the gate electrode 20 and the field plate electrode 21b in the direction X and the side surface of the first trench 15a. For this reason, the capacitance of the MOSFET 2 can be set smaller than that of the semiconductor device 300 to enable high-speed switching.

In the above-described semiconductor devices 100 to 400, since the first insulating film included in the MOSFET 1 not contain a metal, and the second insulating film included in the MOSFET 2 contain a metal, the breakdown can more reliably occurs first in the MOSFET 2.

Particularly, it is preferable that a silicon oxide film be used as the first insulating film and the second insulating film, and lead be used as a metal. It is preferable that a lead concentration in the insulating film containing lead be 0.1% to 0.5% in view of obtaining a stable charge density.

When the first insulating film does not contain a metal, and the second insulating film contains a metal, a defect is formed in the second insulating film, whereby the current leaks, the breakdown occurs first in the MOSFET 2, and the breakdown resistance is improved.

In the semiconductor devices 100 to 400, each of the first insulating film and the second insulating film included in the MOSFET may contain a metal, and a metal density of the second insulating film may be higher than a metal density of the first insulating film. With this configuration, defects are formed more in the second insulating film than in the first insulating film. As a result, the current leaks, the breakdown occurs first in the MOSFET 2, and the breakdown resistance is improved.

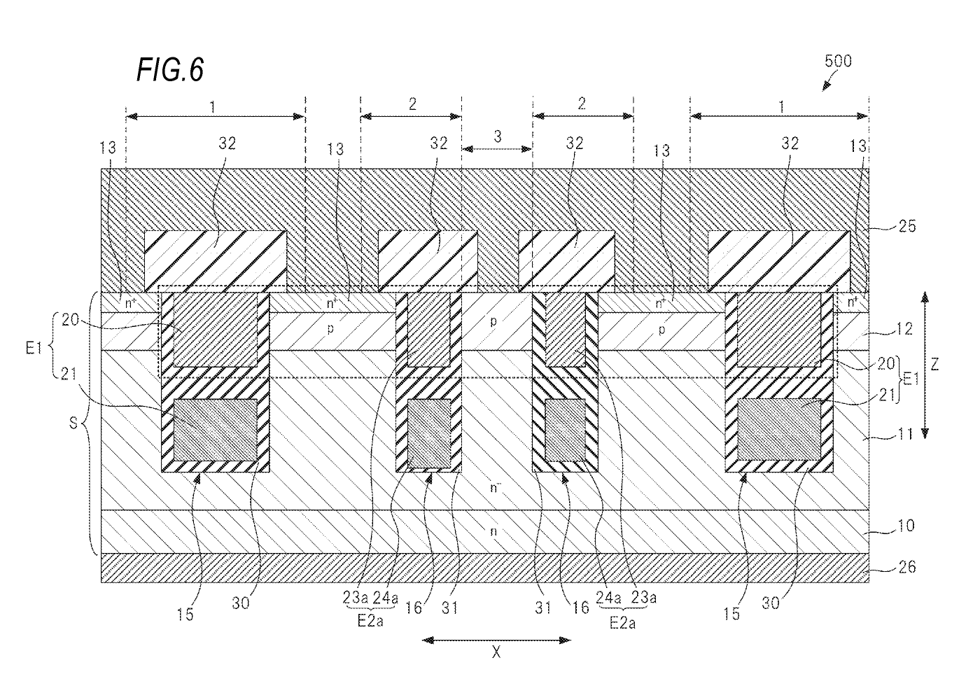

FIG. 6 is a sectional view partially illustrating a schematic configuration of a semiconductor device 500 according to an embodiment of this disclosure. In contrast to the semiconductor device 200 illustrated in FIG. 3, the semiconductor device 500 has a configuration in which a thickness of the second insulating film 31 between the field plate electrode 24a of the right MOSFET 2 and the bottom surface of the second trench 16 is the same as the first thickness L1 (see FIG. 2A) of the first insulating film 30 of the MOSFET 1.

In the semiconductor device 500, a breakdown can occur in a left MOSFET 2 of two MOSFETs 2 earlier than that in the other MOSFET 1 or 2. As a result, the breakdown resistance can be improved.

Even in the semiconductor device 100 illustrated in FIG. 1, for example, the second trench 16 of the right MOSFET 2 can be replaced with the first trench 15.

Similarly, even in the semiconductor device 300 illustrated in FIG. 4 or the semiconductor device 400 illustrated in FIG. 5, for example, the second trench 16a of the right MOSFET 2 can be replaced with the first trench 15a.

In addition, as the transistor included in the semiconductor devices 100 to 500, the MOSFET is exemplified in the above description. However, even when the transistor is an IGBT, the similar effects can be obtained with the similar configuration.

In addition, even when the semiconductor devices 100 to 500 are configured such that the p-type and the n-type of the impurity region in the semiconductor substrate S are reversed, the similar effects can be obtained.

In the semiconductor devices 100 to 500 illustrated in FIGS. 1 to 6, the MOSFET 1 in the right end or the left end may be removed. Even in this configuration, the breakdown can occur in the MOSFET 2 having a relatively thin thickness in the vicinity of the bottom surface of the trench earlier than that in the MOSFET 1, so that breakdown resistance can be improved.

In above description, the lower end of the trench of the MOSFET 1 and the lower end of the trench of the MOSFET 2 are formed in the same position. However, this disclosure is not limited thereto, and, for example, the lower end of the trench of the MOSFET 2 may be formed above the lower end of the trench of the MOSFET 1.

Further, the field plate electrode included in the MOSFET 1 and the MOSFET 2 is not essential, and may be omitted.

In a case where the field plate electrode is omitted in FIG. 1, the trench portion in a range enclosed by a broken line in FIG. 1 may be removed, and the trench may be united upward. The field plate electrodes 21 and 24 may be configured to have a function as a gate electrode.

In a case where the field plate electrode is omitted in FIG. 3, the trench portion in a range enclosed by a broken line in FIG. 3 may be removed, and the trench may be united upward. The field plate electrodes 21 and 24a may be configured to have a function as a gate electrode.

In a case where the field plate electrode is omitted in FIG. 4, the trench portion in a range enclosed by a broken line in FIG. 4 may be removed, and the trench may be united upward. The field plate electrodes 21a and 24b may be configured to have a function as a gate electrode.

In a case where the field plate electrode is omitted in FIG. 5, the trench portion in a range enclosed by a broken line in FIG. 5 may be removed, and the trench may be united upward. The field plate electrodes 21b and 24c may be configured to have a function as a gate electrode.

In a case where the field plate electrode is omitted in FIG. 6, the trench portion in a range enclosed by a broken line in FIG. 6 may be removed, and the trench may be united upward. The field plate electrodes 21 and 24a may be configured to have a function as a gate electrode.

1. A semiconductor device comprising:
three or more transistors, which are formed on a semiconductor substrate and arranged in one direction; and
a PN junction diode, which is formed in a part of a region between adjacent ones of the three or more transistors formed on the semiconductor substrate,
wherein each of the three or more transistors includes:
a trench, which is formed inwardly from a front surface of the semiconductor substrate;
a conductive region, which is configured by at least one conductor formed in the trench; and
an insulating film, which is formed in a portion of the trench in which the conductive region is not formed, and
wherein
a first trench is the trench of a transistor of the three or more transistors which is not adjacent to the PN junction diode,
a first conductive region is the conductive region of the transistor which is not adjacent to the PN junction diode, and
a first insulating film is the insulating film of the transistor which is not adjacent to the PN junction diode,
wherein
a second trench is the trench of one or both of two transistors of the three or more transistors, which are adjacent to the PN junction diode,
a second conductive region is the conductive region of the one or both of transistors,
a second insulating film is the insulating film of the one or both of the two transistors,
wherein a first thickness of the first insulating film is a thickness between an end portion of the first conductive region on a bottom surface side of the first trench and a bottom surface of the first trench wherein a second thickness of the second insulating film is a thickness between an end portion of the second conductive region on a bottom surface side of the second trench and a bottom surface of the second trench, and
wherein the first thickness is thicker than the second thickness.

2. The semiconductor device according to claim 1, wherein the second thickness is 0.2 times to 0.8 times of the first thickness.

3. The semiconductor device according to claim 1,
wherein a third thickness of the first insulating film is a thickness between each end in a direction of the end portion of the first conductive region on the bottom surface side of the first trench and a side surface of the first trench,
wherein a fourth thickness of the second insulating film is a thickness between each end in the direction of the end portion of the second conductive region on the bottom surface side of the second trench and a side surface of the second trench, and
wherein the third thickness is equal to the fourth thickness.

4. The semiconductor device according to claim 1,
wherein the end portion of the first conductive region on the bottom surface side of the first trench is a plane parallel to the front surface of the semiconductor substrate,
wherein the bottom surface of the first trench is a curved surface protruding in a direction apart from the front surface of the semiconductor substrate,
wherein the end portion of the second conductive region on the bottom surface side of the second trench is a curved surface protruding in the direction apart from the front surface of the semiconductor substrate, and
wherein the bottom surface of the second trench is a curved surface protruding in the direction apart from the front surface of the semiconductor substrate.

5. (canceled)

6. (canceled)
